(19) United States
(12) Patent Application Publication
(10) Pub. No.: US 2009/0147481 A1
(43) Pub. Date: Jun. 11, 2009

(54) ELECTRONIC DEVICE

(75) Inventor: Akiya Shimoura, Kanagawa (JP)

Correspondence Address: PEARNE & GORDON LLP, 1801 EAST 9TH STREET, SUITE 1200, CLEVELAND, OH, 44114-3108, US

(73) Assignee: MATSUSHITA ELECTRIC INDUSTRIAL CO., LTD., Osaka (JP)

(21) Appl. No.: 11/719,595

(22) PCT Filed: Aug. 2, 2006
(86) PCT No.: PCT/JP06/15317

§ 371 Date: May 17, 2007

(30) Foreign Application Priority Data
Aug. 3, 2005 (JP) 2005-225369

(51) Int. Cl. H05K 7/20

(52) U.S. Cl. 361/720

(57) ABSTRACT

Provided is an electronic device, which can make the user feel no temperature difference, which can keep the heat liberation of a casing and which can be reduced in size.

The electronic device 10 is constituted such that a circuit board 12 having electronic parts 11 packaged thereon is housed in a casing 13, such that projections 15 and pits 16 are relatively formed in the outer face 13A of the casing 13, and such that the projections 15 are provided with an heat insulating layer 18 on its tops 15A. In this electronic device 10, the projections 15 and the pits 16 of the casing 13 are formed to follow the contours of the electronic parts 11 with respect to the circuit board 12.

### TECHNICAL FIELD

The present invention relates to an electronic device, in which a circuit board having electronic parts packaged thereon is housed in a casing.

### BACKGROUND ART

The electronic device of the recent years has tendencies, in which it is remarkably improved in the size reduction and in the packaging density and in which the power consumption is increased by multiple functions.

Of the surface of the casing forming the frame of the electronic device, accordingly, a surface temperature difference occurs at a specific portion as the electronic device is used for a long time, and a user may feel abnormal when the user holds the electronic device with the hands.

In order to eliminate this surface temperature difference, it is necessary to perform the heat liberation properly. As the method for performing the heat liberation properly, there has been known a fan air-cooling method, in which the hot air in the casing is discharged by a fan to the outside, or a natural air-cooling method, in which the heat is diffused to a heat liberation plate.

Here, the fan air-cooling method uses a fan so that it obstructs the size/thickness reduction seriously. In addition, the fan air-cooling method is not desired from the viewpoint of current consumptions and noises, and the natural air-cooling method using no fan is preferred.

However, the natural air-cooling method may confine the heat in the casing so that it finds it difficult to keep the surface temperature of the casing properly.

Here, the electronic device of the prior art uses the casing made of a resin, but the casing has recently transferred to one made of a magnesium alloy.

This is because the magnesium alloy is enabled to reduce the weight and to improve the recycling percentage by thinning the casing, to retain the high-grade feel by the metallic design intrinsic to the metal, and to improve the heat liberation.

When the electronic device is used for a long time with the metallic casing of the magnesium alloy or the like, however, a relatively large surface temperature difference may occur at a specific portion of the casing thereby to cause the user to feel abnormal when the user holds the casing with the hands.

Thus, an electronic device for reducing a temperature feeling sense has been proposed (in Patent Document 1; for example) by forming a heat insulating film at such a portion of the surface of the metallic casing as has a relatively large surface temperature difference. In the electronic device of Patent Document 1, the circuit board having electronic parts packaged thereon is housed in the casing, and a heat insulating film is formed on the surface of the casing.

Patent Document 1: JP-A-2000-148306

### DISCLOSURE OF THE INVENTION

### Problems that the Invention is to Solve

If the casing is covered on its surface with the heat insulating film, however, the area to contact with the air may be reduced to deteriorate the heat liberating effect.

Moreover, the coverage becomes a factor to increase the thickness size of the electronic device, which is desired to reduce the size and the thickness.

The invention has been contemplated to solve the aforementioned problems, and has an object to provide an electronic device, which can make the user feel no temperature difference, which can keep the heat liberation of a casing and which can be reduced in size.

### Means for Solving the Problems

In an electronic device according to the invention, a circuit board having electronic parts packaged thereon is housed in a casing. The electronic device includes projections and pits relatively formed on the outer face of said casing, and a heat insulating layer disposed on the tops of said projections.

The projections and the pits are formed on the outer face of the casing. When the user touches the outer face of the casing, therefore, the user is blocked against the pits by the projections.

By forming the heat insulating layer on the tops of the projections, it is possible to suppress the touching temperature of the portion (i.e., the heat insulating layer), which is touched by the user.

As a result, it is possible to establish no large surface temperature difference in such a portion of the outer face of the casing as is touched by the user.

Moreover, the projections and the pits are formed on the outer face of the casing so that standing faces (or the so-called “side walls”) are formed between the tops of the projections and the bottoms of the pits.

As a result, not only the bottoms of the pits but also the standing faces can be used as the liberation portions of the heat thereby to retain the heat liberation area sufficiently.

Moreover, the electronic device of the invention is characterized in that said projections and said pits are formed to follow the contours of said electronic parts with respect to said circuit board.

By forming the projections and the pits to follow the contours of the electronic parts, the clearances between the tops of the projections and the electronic parts can be suppressed small so that the increase in the thickness size of the casing can be suppressed to keep the casing at a proper thickness size.

Moreover, the electronic device of the invention is characterized in that said pits are continued in a channel shape.

By continuing the pits in the channel shape, the air is enabled to flow smoothly in straightened streams thereby to improve the cooling effect better.

Moreover, the electronic device is characterized in that said pits are provided in plurality and juxtaposed to each other.

By juxtaposing the pits to each other, the casing can be provided on its outer face with a plurality of passages, in which the air can flow smoothly in the straightened streams.

As a result, much air can flow smoothly in the straightened streams along the outer face of the casing thereby to improve the cooling effect better.

Moreover, the electronic device is characterized in that said pits are provided in plurality and formed generally in a lattice shape.

The plural pits are formed generally in the lattice shape so that lattice-shaped flow straighteners are formed in the outer face of the casing. Thus, the lattice-shaped flow straighteners can flow smoothly in the straightened streams in two directions.

As a result, much air can flow smoothly in the straightened streams to improve the cooling effect better.

Moreover, the electronic device of the invention is characterized in that said electronic parts contact with the inner face of said casing.

By causing the electronic parts to contact with the inner face of the casing, the heat transfer at the time when the heat of the electronic parts is transferred to the casing can be improved to improve the cooling effect better.

Moreover, the electronic device of the invention is characterized in that a heat transfer member is sandwiched between said electronic parts and the inner face of said casing.

By sandwiching the heat transfer member between the electronic parts and the inner face of the casing, the heat transfer at the time when the heat of the electronic parts is transferred to the casing can be improved to improve the cooling effect better.

Since the heat transfer members are sandwiched between the electronic parts and the inner face of the casing, moreover, the assembly tolerances can be absorbed by the heat transfer members to suppress the sizing precision and the packaging precision of the electronic parts 11 and the casing 13 to low levels.

### Advantage of the Invention

According to the invention, a large surface temperature difference is not made at the portion which is touched by the user, there is attained an effect that the user is enabled not to feel the temperature difference (or an abnormal feel) when the user touches the insulating layer.

According to the invention, moreover, not only the bottoms of the pits but also the standing faces are used as heat liberating portions thereby to provide an effect that a sufficient heat liberation area can be retained to keep the heat liberation of the casing.

### BRIEF DESCRIPTION OF THE DRAWINGS

FIG. 1 is a sectional view showing an electronic device of a first mode of embodiment according to the invention.

FIG. 2 is a sectional view showing an example of comparison.

FIG. 3 is a perspective view showing a casing of the electronic device according to the first mode of embodiment.

FIG. 4 is a perspective view showing an electronic device of a second mode of embodiment according to the invention.

FIG. 5 is a perspective view showing an electronic device of a third mode of embodiment according to the invention.

FIG. 6 is a sectional view showing an electronic device of a fourth mode of embodiment according to the invention.

### DESCRIPTION OF REFERENCE NUMERALS AND SIGNS

10, 30, 40 and 50 Electronic Device

11 Electronic Parts

11A Contours

12 Circuit Board

13 Casing

13A Outer Face of Casing

13B Back of Casing

15 Projections

15A Tops of Projections

16, 31 and 41 Pits

18 Heat Insulating Layer

20 and 32 Flow Straighteners

51 and 52 Heat Transfer Members

### BEST MODE FOR CARRYING OUT THE INVENTION

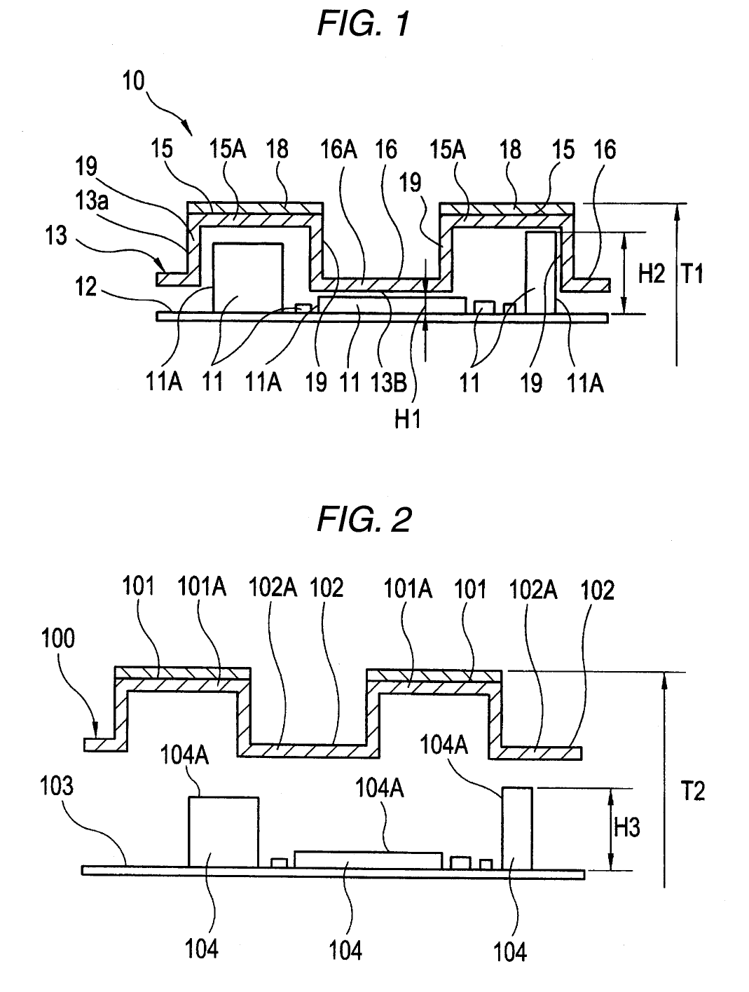

In an electronic device 10 of a first mode of embodiment, as shown in FIG. 1, a circuit board 12 having electronic parts 11 packaged thereon is housed in a casing 13. Projections 15 and pits 16 are relatively formed on the outer face 13A of the casing 13, and a heat insulating layer 18 are formed on the tops 15A of the projections 15.

The casing 13 is made of a metal such as an alloy of magnesium. The projections 15 are formed in plurality on the outer face 13A of the casing 13, and its individual tops 15A are flush with each other. On the other hand, the pits 16 are sized to prevent intrusion of the finger of a user.

The projections 15 and the pits 16 are formed on the outer face 13a of the casing 13 so that the pits 16 can be protected against the intrusion of the user's finger by the projections 15, when the user touches the casing 13.

In addition, the tops 15A of the projections 15 are provided with the insulating layer 18 so that the user touches the insulating layer 18.

This insulating layer 18 is formed by applying or adhering a heat insulating material to the tops 15A. As a result, the heat of the tops 15A is not transferred to the insulating layer 18 so that the touching temperature (or the surface temperature) of the insulating layer 18 can be suppressed low.

Thus, the surface temperature of the insulating layer 18, i.e., the surface temperature of the portion to be touched by the user can be made not to establish a large temperature difference from that of the remaining portions.

Therefore, the user does not feel the temperature difference (or an abnormal feel) when the user touches the insulating layer 18.

In the electronic device 10 of the first mode of embodiment, moreover, the projections 15 and the pits 16 of the casing 13 are formed to follow the contours 11A of the electronic parts 11 with respect to the circuit board 12.

Since the projections 15 and the pits 16 are thus formed to follow the contours 11A of the electronic parts 11, the bottoms 16A of the pits 16 can be brought close to the height H1 of the electronic parts 11 of the smaller height.

As a result, the tops 15A of the projections 15 can be brought close to the height H2 of the electronic parts 11 of the larger height so that the thickness size T1 of the casing 13 can be kept proper without enlarging itself.

In short, the electronic device 10 constitutes the casing 13 with such corrugations as to bury the undulations between the electronic parts 11 so that the clearances between the casing 13 and the electronic parts 11 can be eliminated to make a compact constitution (or a small size).

In the example of comparison shown in FIG. 2, on the contrary, projections 101 and pits 102 of a casing 100 do not follow the contours 104A of electronic parts 104 with respect to a circuit board 103. In this case, the bottoms 102A of the pits 102 have to be arranged above the larger height H3 of the higher electronic parts 104. As a result, the tops 101A of the projections 101 are spaced a long distance from the height H3 of the higher electronic parts 104 thereby to enlarge the thickness size T2 of the casing 100.

Reverting to FIG. 1, in the electronic device 10 of the first mode of embodiment, the projections 15 and the pits 16 are formed on the outer face 13A of the casing 13. As a result, standing faces 19 (or the so-called “side walls”) are formed between the tops 15A of the projections 15 and the bottoms 16A of the pits 16 so that the contact areas with the air can be retained therethrough.

As a result, not only the bottoms 16A of the pits 16 but also the standing faces 19 become heat liberating portions so that a sufficient heat liberation area can be retained.

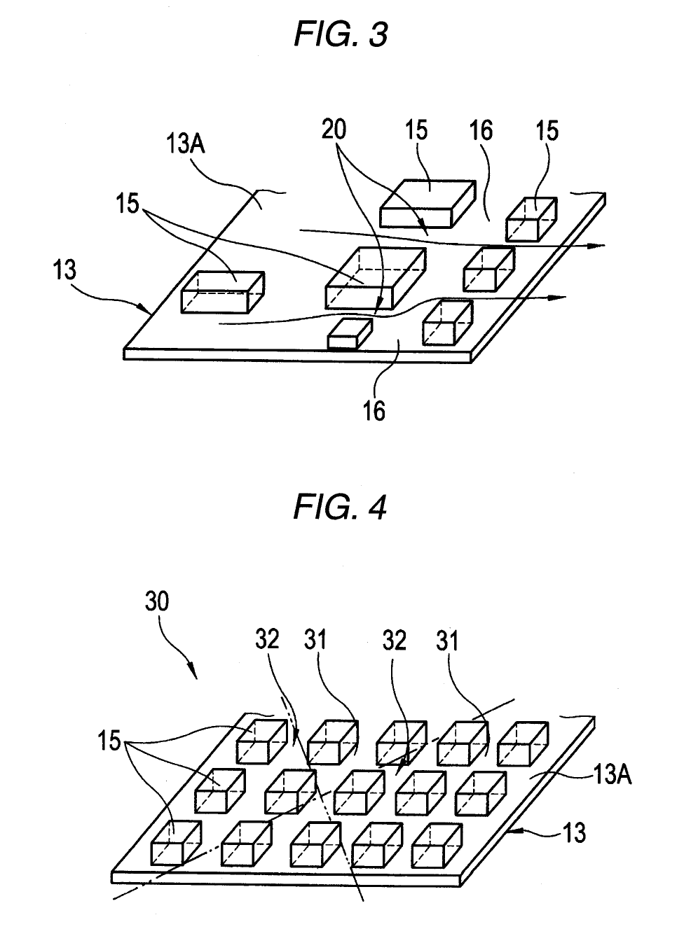

Here, the pits 16, as formed in the outer face 13A of the casing 13, are juxtaposed to each other, as shown in FIG. 3. As a result, flow straighteners 20 are formed by the pits 16 on the outer face 13A of the casing 13.

These flow straighteners 20 are passages for guiding the air to flow smoothly in straightened streams, as indicated by arrows, along the outer face 13A of the casing 13.

As a result, the air flows smoothly in straightened streams along the outer face 13A of the casing 13 so that it can liberates the heat satisfactorily from the casing 13 thereby to cool the casing 13.

Here according to the electronic device 10 of the first mode of embodiment, the projections 15 and the pits 16 are formed on the outer face 13A of the casing 13 so that the casing 13 can have its geometrical moment of inertia increased to provide an effect to enhance the strength of the casing 13.

Moreover, the projections 15 and the pits 16 are formed on the outer face 13A of the casing 13 thereby to provide an effect that flaws are harder to appear than the casing having all faces made flat.

In addition, the insulating layer 18 is made of a resin or rubber thereby to provide an effect that the projections 15 can have their corners prevented from being deformed.

Next, second to fourth mode of embodiments are described with reference to FIG. 4 to FIG. 6. In the second to fourth mode of embodiments, the same or similar members of those of the electronic device 10 of the first mode of embodiment are omitted in their descriptions by designating them by the common reference numerals.

### Second Mode of Embodiment

As shown in FIG. 4, an electronic device 30 of the second mode of embodiment has a plurality of pits 31 formed in the outer face 13A of the casing 13, and the individual pits 31 are formed generally in a lattice shape. The remaining constitution is similar to that of the electronic device 10 of the first mode of embodiment.

Here, the electronic parts 11 (as referred to FIG. 1) are matrix- or partition-packaged in advance at such predetermined positions that the pits 31 form the lattice-shaped grooves.

The pits 31 are formed generally in the lattice shape in the outer face 13A of the casing 13 so that lattice-shaped flow straighteners 32 are formed, as indicated by imaginary lines in the outer face 13A of the casing 13.

Thus, the lattice-shaped flow straighteners 32 can guide the air on the side of the outer face 13A of the casing 13 to flow smoothly in the straightened streams in two directions.

As a result, much air can flow smoothly in the straightened streams to liberate the heat of the casing 13 more satisfactorily thereby to cool the casing 13.

According to the electronic device 30 of the second mode of embodiment, moreover, it is possible to achieve the effects similar to those of the electronic device 10 of the first mode of embodiment.

### Third Mode of Embodiment

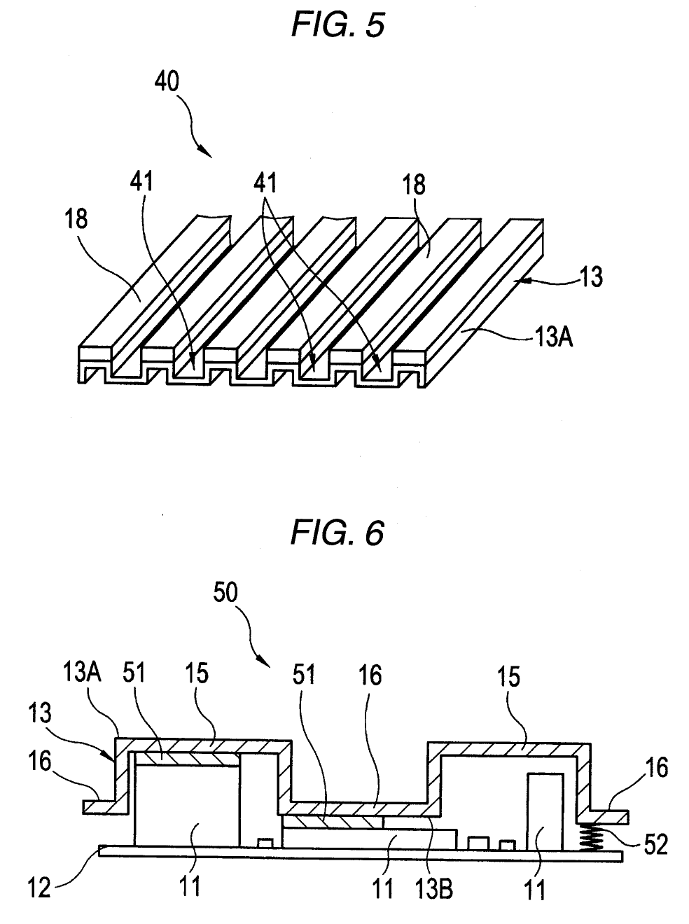

As shown in FIG. 5, an electronic device 40 of the third mode of embodiment has a plurality of pits 41 formed individually in continuous channels in the outer face 13A of the casing 13. The remaining constitution is similar to that of the electronic device 10 of the first mode of embodiment.

Here, the electronic parts 11 (as referred to FIG. 1) are matrix- or partition-packaged in advance at such predetermined positions that the pits 41 form the channel shapes individually.

The pits 41 are continued in the channel shapes in the outer face 13A of the casing 13 so that the air can be made to flow smoothly in the straightened streams along the pits 41.

As a result, much air can flow smoothly in the straightened streams to liberate the heat of the casing 13 more satisfactorily thereby to cool the casing 13.

According to the electronic device 40 of the third mode of embodiment, moreover, it is possible to achieve the effects similar to those of the electronic device 10 of the first mode of embodiment.

As shown in FIG. 6, an electronic device 50 of the fourth mode of embodiment is constituted such that heat transfer members 51 and 52 are sandwiched between the inner face 13B of the casing 13 and the electronic parts 11. The remaining constitution is similar to that of the electronic device 10 of the first mode of embodiment.

The heat transfer members 51 are made of a sheet-shaped material having a high heat conductivity, for example.

The heat transfer members 51 and 52 are made of a spring member having a high heat conductivity, for example.

By sandwiching the heat transfer members 51 and 52 between the electronic parts 11 and the inner face 13B of the casing 13, the electronic parts 11 and the inner face 13B of the casing 13 are made to contact (closely) with each other through the heat transfer members 51 and 52.

As a result, the heat transfer at the time when the heat of the electronic parts 11 to the casing 13 is transferred is improved to provide a constitution, in which the heat is hardly confined, thereby to improve the cooling effect better.

Since the heat transfer members 51 and 52 are sandwiched between the electronic parts 11 and the inner face 13B of the casing 13, moreover, the assembly tolerances can be absorbed by the heat transfer members 51 and 52 to suppress the sizing precision and the packaging precision of the electronic parts 11 and the casing 13 to low levels.

According to the electronic device 50 of the fourth mode of embodiment, moreover, it is possible to achieve the effects similar to those of the electronic device 10 of the first mode of embodiment.

### Modification of Fourth Mode of Embodiment

The electronic device 50 of the fourth mode of embodiment has been described on the example, in which the heat transfer members 51 and 52 are sandwiched between the inner face 13A of the casing 13 and the electronic parts 11. However, the invention should not be limited to that example, but the electronic parts 11 can also be made to contact with the inner face 13B of the casing 13.

By making the electronic parts 11 contact the inner face 13B of the casing 13 directly, the contact between the electronic parts 11 and the inner face 13B of the casing 13 is further increased.

As a result, the heat transfer at the time when the heat of the electronic parts 11 to the casing 13 is transferred is improved to provide a constitution, in which the heat is hardly confined, thereby to improve the cooling effect better.

Incidentally, it is possible to change the shapes and sizes of the projections 15 and the pits 16, 31 and 41, as exemplified in the aforementioned modes of embodiment, suitably.

The present application is based on Japanese Patent Application (JP2005-225369) filed in the Japanese Patent Office on Aug. 3, 2005, the contents of which are incorporated herein by reference.

### INDUSTRIAL APPLICABILITY

The invention is suitably applied to an electronic device, in which a circuit board having electronic parts packaged thereon is housed in a casing.

1. An electronic device, in which a circuit board having electronic parts packaged thereon is housed in a casing, comprising:
projections and pits relatively formed on an outer face of said casing; and
a heat insulating layer disposed on tops of said projections.

2. An electronic device as set forth in claim 1, wherein said projections and said pits are formed to follow contours of said electronic parts with respect to said circuit board.

3. An electronic device as set forth in claim 1, wherein said pits are continued in a channel shape.

4. An electronic device as set forth in claim 1, wherein said pits are provided in plurality and juxtaposed to each other.

5. An electronic device as set forth in claim 1, wherein said pits are provided in plurality and formed generally in a lattice shape.

6. An electronic device as set forth in claim 1, wherein said electronic parts contact with an inner face of said casing.

7. An electronic device as set forth in claim 6, wherein a heat transfer member is sandwiched between said electronic parts and the inner face of said casing.
